(19) United States
(12) Patent Application Publication
(10) Pub. No.: US 2025/0120061 A1
(43) Pub. Date: Apr. 10, 2025

(54) 3D DRAM WITH ENLARGE-LESS TRIM

(71) Applicant: Applied Materials, Inc., Santa Clara, CA (US)

(72) Inventor: Chang Seok KANG, Santa Clara, CA (US)

(73) Assignee: Applied Materials, Inc., Santa Clara, CA (US)

(21) Appl. No.: 18/905,982

(22) Filed: Oct. 3, 2024

Related U.S. Application Data
(60) Provisional application No. 63/588,931, filed on Oct. 9, 2023.

(51) Int. Cl. H10B 12/00; H01L 21/02

(52) U.S. Cl. CPC H10B 12/05; H01L 21/0223; H01L 21/02247; H01L 21/02252; H01L 21/02274; H01L 21/02532; H10B 12/03; H10B 12/30

(57) ABSTRACT

Embodiments of the present technology may include semiconductor processing methods and systems. Methods and systems may include providing a substrate to a processing region of a semiconductor processing chamber, where the substrate includes one or more alternating pairs of a semiconductor material layer and a sacrificial material layer. Methods include forming one or more vertically extending features through the one or more alternating pairs of semiconductor material layer and sacrificial material layer, forming one or more sidewalls having alternating exposed lateral ends of the semiconductor material and the sacrificial material. Methods include forming a protective material layer over the exposed lateral ends of the semiconductor material layer. Methods include laterally recessing at least a portion of the sacrificial material layer from the one or more vertically extending features and trimming a portion of the semiconductor material layer adjacent to the one or more vertically extending features.

### CROSS-REFERENCES TO RELATED APPLICATIONS

This application claims the benefit of priority to U.S. Patent Application No. 63/588,931 filed Oct. 9, 2023, the contents of which are hereby incorporated by reference in their entirety for all purposes.

### TECHNICAL FIELD

The present technology relates to semiconductor systems and processes. More specifically, the present technology relates to three-dimensional (3D) dynamic random-access memory (DRAM) devices (3D DRAM), and methods of forming such devices.

### BACKGROUND

Integrated circuits are made possible by processes which produce intricately patterned material layers on substrate surfaces. Producing patterned material on a substrate requires controlled methods of formation and removal of exposed material. Material characteristics may affect how the device operates, and may also affect how the films are removed relative to one another. During formation and removal, materials may be subject to unintended removal, which may result in wasted space within the device. Such wasted area within a device becomes increasing problematic as devices continue to shrink.

Thus, there is a need for improved systems and methods that can be used to produce high quality devices and structures. These and other needs are addressed by the present technology.

### SUMMARY

The present technology is generally directed to semiconductor devices and methods of forming such devices. Methods include providing a substrate to a processing region of a semiconductor processing chamber, where the substrate includes one or more alternating pairs of a semiconductor material layer and a sacrificial material layer. Methods include forming one or more vertically extending features through the one or more alternating pairs of semiconductor material layer and sacrificial material layer. Methods include forming one or more sidewalls that have alternating exposed lateral ends of the semiconductor material layer and the sacrificial material layer. Methods include forming a protective material layer over the exposed lateral ends of the semiconductor material layer. Methods include laterally recessing at least a portion of the sacrificial material layer from the one or more vertically extending features. Methods include trimming a portion of the semiconductor material layer adjacent to the one or more vertically extending features.

In embodiments, methods include where the protective material layer is formed by selective oxidation or nitridation of the exposed lateral ends of the semiconductor material. In further embodiments, methods include where the sacrificial material is laterally recessed before forming the protective material layer. Moreover, in embodiments, methods also include filling the laterally recessed portion of the sacrificial material with a dielectric material. Additionally or alternatively, methods include removing the dielectric material prior to trimming. In more embodiments, the protective material layer is formed by directional deposition on the exposed lateral ends of the semiconductor material. Furthermore, in embodiments, a thickness of the protective material layer is from about 5 Å to about 500 Å. In more embodiments, the semiconductor material layer is an optionally doped silicon material, and the sacrificial material layer includes silicon germanium. In embodiments, the one or more vertically extending features has a first width prior to the trimming the semiconductor material layer and a second width after the trimming of the semiconductor material layer, where the second width is less than or about 10% larger than the first width. In further embodiments, the semiconductor material layer has a thickness that is greater than or about 400% more than a thickness of the sacrificial material layer. In embodiments, methods include removing the protective material layer after trimming the semiconductor material layer.

The present technology is also generally directed to methods of semiconductor processing. Methods include, providing a substrate to a processing region of a semiconductor processing chamber, where the substrate includes alternating pairs of a silicon-containing material and a silicon-and-germanium-containing material. Methods include etching one or more access apertures through the alternating pairs of the silicon-containing material and the silicon-and-germanium-containing material, exposing lateral ends of the alternating pairs of the silicon-containing material and the silicon-and-germanium-containing material. Methods include where the etching forms one or more sidewalls containing the alternating exposed lateral ends of the alternating pairs of the silicon-containing material and the silicon-and-germanium-containing material. Methods include forming a protective material layer over the exposed lateral ends of the silicon-containing material. Methods include laterally recessing at least a portion of the silicon-and-germanium-containing material from the one or more access apertures. Methods include trimming a portion of silicon-containing material adjacent to the access aperture.

In embodiments, the substrate includes greater than 20 alternating pairs of the silicon-containing material and the silicon-and-germanium-containing material. In more embodiments, a thickness of the silicon-and-germanium-containing material is less than or about 30 nm. Furthermore in embodiments, the silicon-containing material has a thickness that is greater than or about 400% more than a thickness of the silicon-and-germanium-containing material. Additionally or alternatively, in embodiments, methods include etching one or more vertically extending features at an end of the alternating pairs of the silicon-containing material and the silicon-and-germanium-containing material opposed to the exposed lateral ends, exposing outer ends of the alternating pairs of the silicon-containing material and the silicon-and-germanium-containing material, where the etching removes at least a portion of the patterning stack and forms one or more outer sidewalls having the alternating exposed outer ends of the alternating pairs of the silicon-containing material and the silicon-and-germanium-containing material. Methods include forming a second protective layer over the exposed outer ends of the silicon-containing material. In embodiments methods include laterally recessing at least a portion of the silicon-and-germanium-containing material from the one or more vertically extending features. Moreover, in embodiments, methods include trimming a portion of the semiconductor material layer adjacent to the access aperture.

In embodiments, methods include etching one or more vertically extending features at an end of the alternating pairs of the silicon-containing material layer and the silicon-and-germanium-containing material layer opposed to the exposed lateral ends, exposing outer ends of the alternating pairs of the silicon-containing material layer and the silicon-and-germanium-containing material layer. In more embodiments, methods include where the etching removes at least a portion of the patterning stack and forms one or more outer sidewalls having the alternating exposed outer ends of the alternating pairs of the silicon-containing material layer and the silicon-and-germanium-containing material layer. In embodiments, methods include forming a second protective layer over the exposed outer ends of the silicon-containing material.

The present technology is also generally directed to methods of forming a three-dimensional dynamic random-access memory (3D DRAM) device. Methods include providing a substrate to a processing region of a semiconductor processing chamber, where the substrate includes one or more alternating pairs of a silicon-containing material layer and a silicon-and-germanium-containing material layer. Methods include forming one or more access apertures through the one or more alternating pairs of the silicon-containing material layer and the silicon-and-germanium-containing material layer, forming one or more sidewalls comprising alternating exposed lateral ends of the silicon-containing material layer and the silicon-and-germanium-containing material layer. Methods include forming a protective material layer over the exposed lateral ends of the silicon-containing material layer. Methods include laterally recessing at least a portion of the silicon-and-germanium-containing material layer from the one or more access apertures. Methods include trimming a portion of the silicon-containing material layer adjacent to the one or more access apertures.

Such technology may provide numerous benefits over conventional systems and methods of forming 3D-DRAM devices. For example, by forming devices as discussed herein, little to no widening of an access aperture may be required in order to etch a recess within the access aperture, even when the access aperture defines a high aspect ratio structure. Thus, devices and methods discussed herein may provide for increased recess dimensions, such as increased channel dimensions in the case of 3D DRAM. Embodiments of the present technology, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing system according to some embodiments of the present technology.

FIG. 1B shows a schematic cross-sectional view of an exemplary processing system according to some embodiments of the present technology.

FIG. 2 shows operations of an exemplary method of semiconductor processing according to some embodiments of the present technology.

FIGS. 3A-3H show a cross-sectional views of exemplary semiconductor structures according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In dynamic random-access memory (DRAM) devices, such as 3D DRAM, alternating layers of material may be formed on a substrate. The alternating layers of material may include alternating pairs of a silicon-containing material and a silicon-and-germanium-containing material. As the number of layers increase, so does the challenge to form features, due at least in part to the high aspect ratio of the device. For instance, during 3D DRAM processing, a vertically extending access aperture may be formed through two or more layers of material. Subsequent processing may require removal of material extending horizontally away from the access aperture. Such horizontally extending recesses, referred to as “blind recesses” herein due to the lack of line-of-sight to an access aperture, are difficult to properly trim, particularly as devices continue to increase in size while also desiring larger aspect ratios in formed features. While 3D DRAM is utilized as an example of such blind recesses, it should be clear that such challenges may be equally applicable to various devices with one or more blind recesses formed from a main channel.

Initial efforts to improve 3D DRAM devices included increasing the size of SiGe layers as compared to silicon layers. In such a manner, all or a portion of the SiGe may be etched, while retaining the silicon. Thus, a controlled silicon layer and etched portion could be controlled upon deposition of the layers. However, such structures were insufficient for high aspect ratio structures, as only a certain percentage of SiGe could be present without causing mechanical failures. Efforts were made to decrease the germanium concentration without reducing the SiGe layer thickness, but such attempts failed to achieve germanium concentrations necessary for selective etch as compared to silicon. Attempts were made to utilize thinner SiGe layers as compared to silicon, coupled with a silicon recess trim after SiGe removal. However, such efforts caused recessing of the access aperture, disadvantageously recusing the length of the semiconductor channel. In existing methods, a width of an access aperture may more than double in width in order to trim acceptable channels. Such a phenomenon either requires an access aperture of insufficient width to properly trim the blind recess, or in unacceptable dimension loss, particularly as devices continue to shrink.

Surprisingly, the present technology has found that by carefully controlling the deposition and etch operations, excellent trimming can be obtained in one or more blind recesses without increasing a width of an access area (e.g. a sidewall). Namely, by carefully depositing one or more protective films, controlled trimming of a sacrificial material may be achieved while little to no removal of a non-sacrificial material is exhibited. Devices formed according to the present technology may therefore exhibit excellent dimension control, such as in a blind recess, without sacrificing the quality of the trimmed section.

After describing general aspects of a chamber configured to perform operations according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of semiconductor processing chambers and operations.

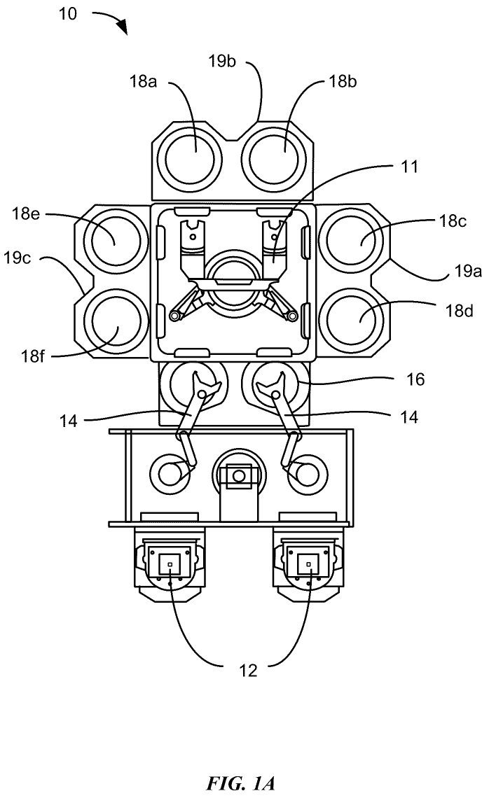

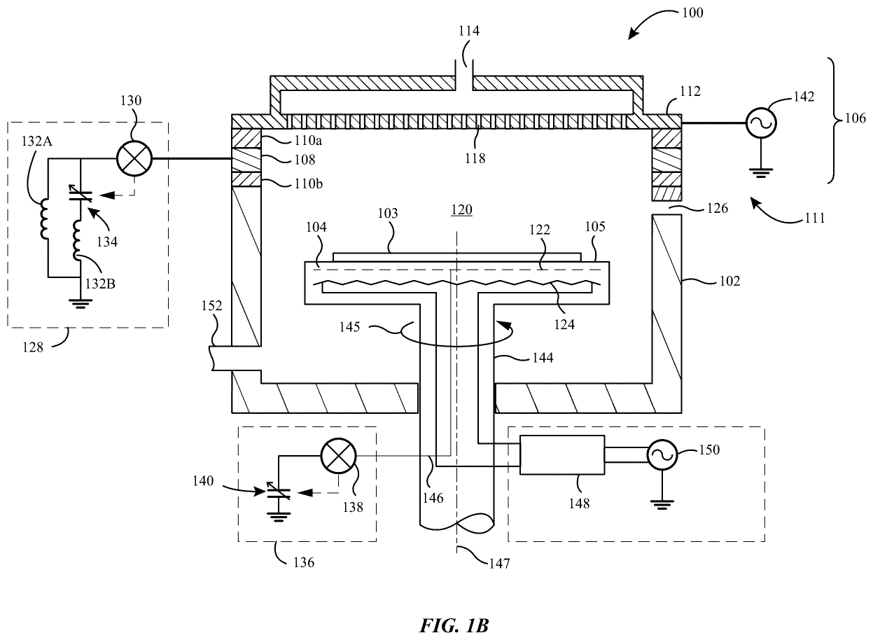

FIG. 1A shows a top plan view of one embodiment of a processing system 10 of deposition, treating, etching, baking, and curing chambers according to embodiments. In the figure, a pair of front opening unified pods 12 supply substrates of a variety of sizes that are received by robotic arms 14 and placed into a low pressure holding area 16 before being placed into one of the semiconductor processing chambers 18a-f, positioned in tandem sections 19a-c. A second robotic arm 11 may be used to transport the substrate wafers from the holding area 16 to the semiconductor processing chambers 18a-f and back. Each semiconductor processing chamber 18a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, plasma treatments, annealing, ashing, etc.

The semiconductor processing chambers 18a-f may include one or more system components for depositing, plasma treating, curing and/or etching a dielectric or other film on the substrate. In one configuration, two pairs of the semiconductor processing chambers, e.g., 18c-d and 18c-f, may be used to deposit dielectric material on the substrate, and the third pair of semiconductor processing chambers, e.g., 18a-b, may be used to treat the deposited dielectric. In another configuration, all three pairs of chambers, e.g., 18a-f, may be configured to deposit and treat stacks of alternating dielectric films on the substrate. Any one or more of the processes described may be carried out in chambers separated from the fabrication system shown in different embodiments. It will be appreciated that additional configurations of deposition, treating, etching, annealing, and curing chambers for dielectric films are contemplated by system 10.

FIG. 1B shows a cross-sectional view of an exemplary semiconductor processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form tensile nitride films according to some embodiments of the present technology, although it is to be understood that the methods may similarly be performed in any chamber within which film formation may occur. The semiconductor processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the semiconductor processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the semiconductor processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the semiconductor processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1B, or the gas distributor 112 may be coupled with ground in some embodiments.

The first electrode 108 may be coupled with a first tuning circuit 128 that may control a ground pathway of the semiconductor processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1B may be used with any semiconductor processing chamber for plasma or thermal processing. In operation, the semiconductor processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the semiconductor processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

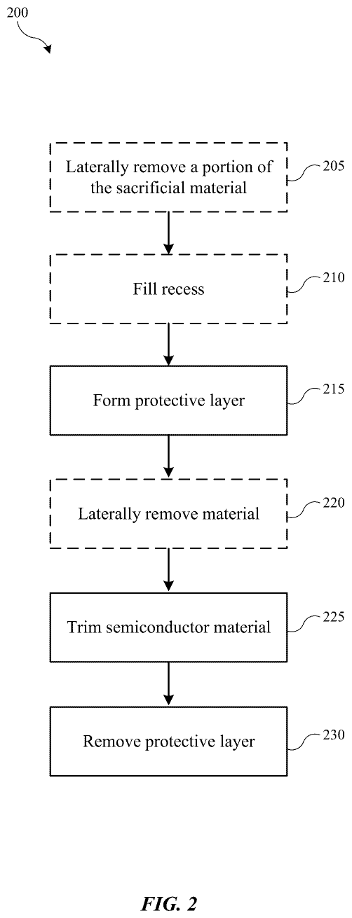

FIG. 2 shows exemplary operations in a method 200 for forming a semiconductor structure according to embodiments of the present technology. Method 200 may include one or more operations prior to the initiation of the method, including front-end processing, deposition, etching, polishing, cleaning, or any other operations that may be performed prior to the described operations. For example, the method may begin after a number of layers have been deposited, such as for producing 3D DRAM structures. However, as explained above, it is to be understood that the figures illustrate just one exemplary process in which processes according to embodiments of the present technology may be employed, and the description is not intended to limit the technology to this process or structure alone. Some or all of the operations may be performed in chambers or system tools as previously described, or may be performed in different chambers on the same system tool, which may include the chamber in which the operations of method 200 may be performed.

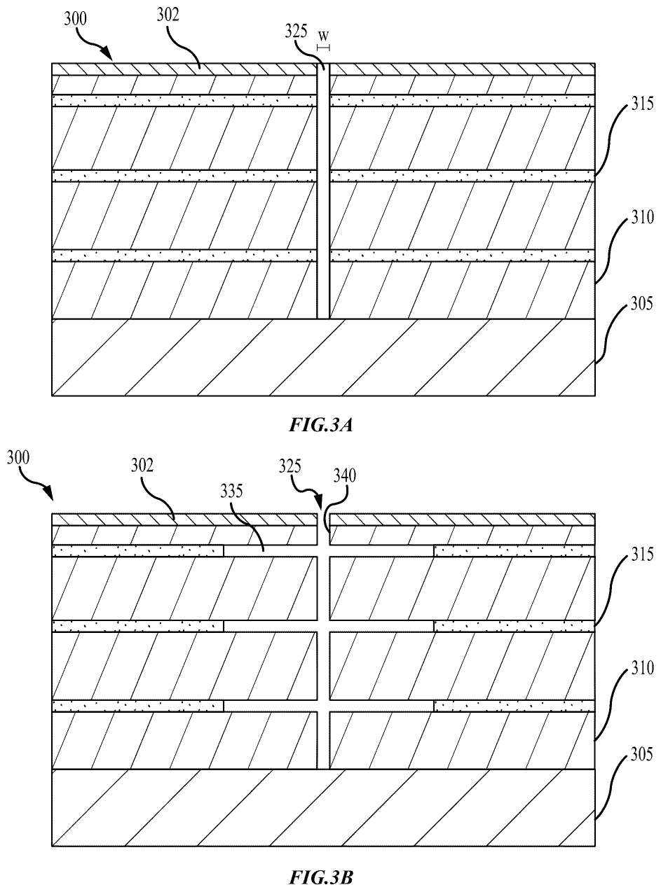

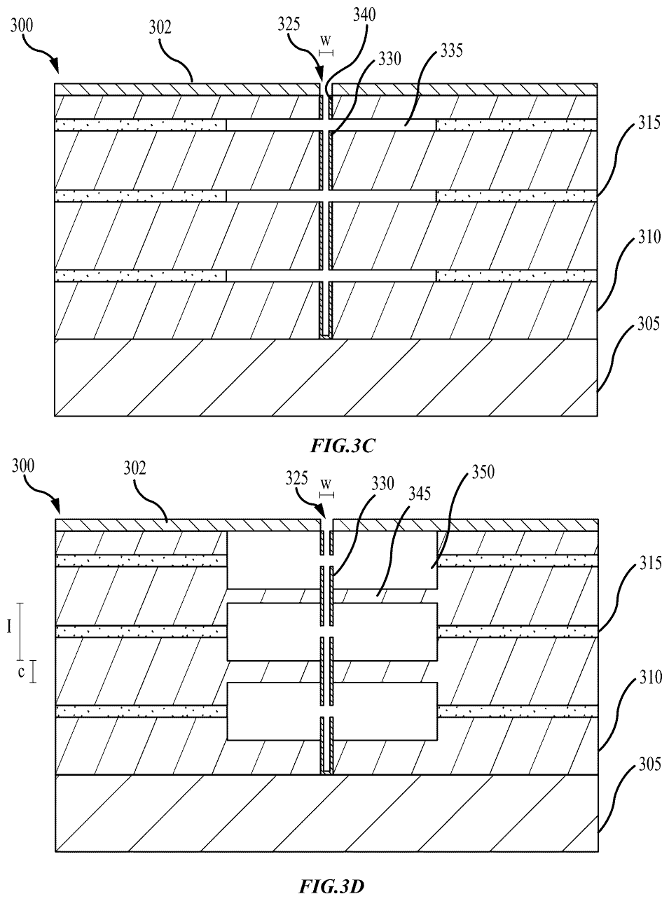

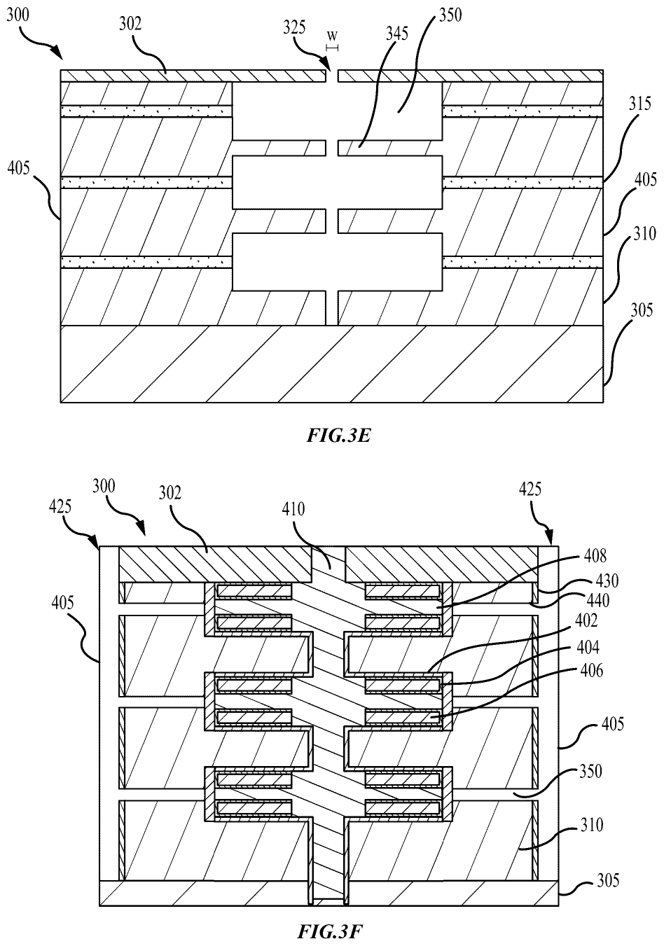

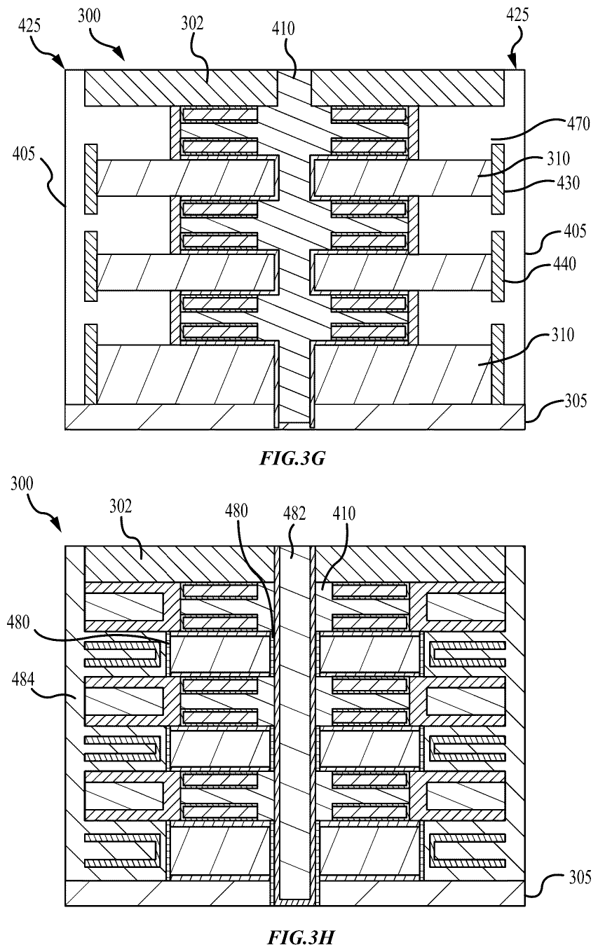

Method 200 may include additional operations prior to initiation of the listed operations. For example, additional processing operations may include forming structures on a substrate, which may include both forming and removing material. Prior processing operations may be performed in the chamber in which method 200 may be performed, or processing may be performed in one or more other semiconductor processing chambers prior to delivering the substrate into the semiconductor processing chamber in which method 200 may be performed. Regardless, method 200 may optionally include delivering a substrate to a processing region of a semiconductor processing chamber, such as semiconductor processing chamber 100 described above, or other chambers that may include components as described above. The substrate may be deposited on a substrate support, which may be a pedestal such as substrate support 104, and which may reside in a processing region of the chamber, such as processing volume 120 described above. Method 200 describes operations shown schematically in FIGS. 3A-3H, the illustrations of which will be described in conjunction with the operations of method 200. It is to be understood that FIGS. 3A-3H illustrate only partial schematic views, and a substrate may contain any number of structural sections having aspects as illustrated in the figures, as well as alternative structural aspects that may still benefit from operations of the present technology. Nonetheless, as illustrated in FIG. 3A, a semiconductor structure 300 may have a number of layers of material deposited overlying the substrate 305. Semiconductor structure 300 may be formed from any number of materials, such as a base wafer or substrate made of silicon or silicon-containing materials, germanium, other substrate materials, as well as one or more materials that may be formed overlying the substrate during semiconductor processing.

As illustrated in FIG. 3A substrate 305 may be any number of materials, such as a base wafer or substrate made of silicon or silicon-containing materials, germanium, other substrate materials, as well as one or more materials that may be formed overlying the substrate during semiconductor processing. In embodiments, the substrate 305 may include bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100>or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 305 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In embodiments, prior processing may form one or more materials on the substrate 305. For example, the substrate may previously be processed alternating pairs of a semiconductor material 310, which may be a silicon-containing material, and a sacrificial material 315, which may be a silicon-and-germanium-containing material, which may be applicable to formation of devices 300, such as a 3D DRAM structure, in embodiments. As illustrated in FIG. 4A, the film stack may be deposited on a substrate 305. The film stack may include multiple unit stacks (e.g., three unit stacks in the illustrated example) that are, in part, used sacrificially to form 3D DRAM cells. As will become apparent, this method forms three layers of 3D DRAM cells. In other examples, repeating the unit stacks of the film stack can enable forming additional layers of 3D DRAM cells. Also, using one instance of the unit stack in the film stack can enable forming one layer of 3D DRAM cells.

Nonetheless, in embodiments, the alternating pairs of the silicon-containing material 310 and the silicon-and-germanium-containing material 315 formed on the substrate may include greater than 10 alternating pairs of the silicon-containing material 310 and the silicon-and-germanium-containing material 315, such as greater than 20 alternating pairs, such as greater than 30 alternating pairs, such as greater than 32 alternating pairs, such as greater than 34 alternating pairs, such as greater than 36 alternating pairs, such as greater than 38 alternating pairs, such as greater than 40 alternating pairs, greater than 44 alternating pairs, greater than 48 alternating pairs, greater than 50 alternating pairs, greater than 52 alternating pairs, greater than 56 alternating pairs, greater than 60 alternating pairs, greater than 64 alternating pairs, greater than 68 alternating pairs, greater than 72 alternating pairs, or any ranges or values therebetween.

A thickness of each pair of the alternating pairs, such as the silicon-and-germanium-containing material 315 and silicon-containing material 31 may be greater than or about 30 nm. In such a manner, adequate space for accommodating insulator volume discussed below is provided. Thus, in embodiments, each pair may have a thickness that is greater than or about 35 nm, such as greater than or about 40 nm, greater than or about 45 nm, greater than or about 50 nm, greater than or about 55 nm, greater than or about 60 nm, greater than or about 65 nm, greater than or about 70 nm, greater than or about 75 nm, greater than or about 80 nm, greater than or about 85 nm, greater than or about 90 nm, greater than or about 95 nm, greater than or about 100 nm, or any ranges or values therebetween.

However, unlike prior cells, the present technology may provide for an increased semiconductor material layer to sacrificial material layer ratio. Namely, the processes and methods discussed herein may provide for deposition and etch that is independent from sacrificial layer selectivity alone. Thus, the semiconductor structure 300 according to the present technology may exhibit improved mechanical strength and stability, as reduced amounts of weak sacrificial layers may be present, while maintaining the necessary overall pair thickness for robust insulator volume formation.

In embodiments, the semiconductor material may have a thickness that is greater than or about 10% more than a thickness of a sacrificial material layer, such as greater than or about 20%, such as greater than or about 30%, such as greater than or about 40%, such as greater than or about 50%, such as greater than or about 60%, such as greater than or about 70%, such as greater than or about 80%, such as greater than or about 90%, such as greater than or about 100%, such as greater than or about 125%, such as greater than or about 150%, such as greater than or about 175%, such as greater than or about 200%, such as greater than or about 250%, such as greater than or about 300%, such as greater than or about 350%, such as greater than or about 400% more, such as greater than or about 450%, such as greater than or about 500%, such as greater than or about 550%, such as greater than or about 600%, such as greater than or about 650%, such as greater than or about 700%, or any ranges or values therebetween.

Due at least in part to the increased thickness of the semiconductor material, the doping content of a sacrificial layer may not be particularly limited. For instance, in embodiment where the sacrificial material is SiGe, the germanium content may range from about 1% to about 50% by weight of the layer without negatively impacting the structural integrity of the device, such as less than or about 45%, such as less than or about 40%, such as less than or about 35%, such as less than or about 30%, such as less than or about 25%, such as less than or about 20%, such as less than or about 15%, such as less than or about 10%, such as less than or about 5%, or such as greater than or about 2.5%, such as greater than or about 5%, such as greater than or about 7.5%, such as greater than or about 10%, such as greater than or about 15%, such as greater than or about 20%, such as greater than or about 25%, such as greater than or about 30%, such as greater than or about 35%, such as greater than or about 40%, such as greater than or about 45%, or any ranges or values therebetween. For instance, due at least in part to the reduced thickness of the sacrificial material layer(s), a higher percentage of germanium may be present without negatively impacting the mechanical stability of the structure.

Regardless of the ratio of semiconductor layer 310 to sacrificial layer 315, as illustrated in FIG. 3A, semiconductor device 300 may have an access aperture 325 formed therein. While only one access aperture 325 is illustrated, it should be clear that more than one access aperture may be provided based upon the device, and the device orientation. Nonetheless, the access aperture 325 may be formed through one or more cells of the semiconductor device 300, providing access to each layer of the cell. In embodiments, access aperture(s) 325 may be formed by any methods as known in the art. For instance, in embodiments, access aperture(s) 325 may be patterned utilizing mask 302, and then etched. As illustrated, the etching may be any etch suitable for extending through both a semiconductor material 310 and a sacrificial material 315.

As illustrated in FIG. 3B, optional operation 205 may include laterally removing a portion of the sacrificial material 315. By removing a portion of the sacrificial material, one or more additional deposition operations may be possible for forming protective layer 330 (FIG. 3C). While one or more removal processes may be possible at operation 205 based upon the semiconductor material and sacrificial material selected, in some embodiments, the etching process is a selective isotropic etching process (e.g., a selective dry etching process or a selective wet etching process). In embodiments the extent of which the sacrificial material 315 is laterally removed is controlled by duration of the etching process. For instance, in embodiments, the sacrificial material 315 may be removed laterally based upon a desired length of the channel and isolation recess. In some embodiments, the selective wet etching process may include a hydro fluoride (HF), fluoride (F2) or NH4OH etchant.

While in embodiments, no initial removal of the sacrificial material at operation 205 may be necessary, as will be discussed in greater detail below, when utilized, it may be desirable to at least partially fill the formed recess 335 at optional operation 210. For instance, utilizing one or more non-line of sight deposition methods, such as atomic layer deposition (ALD) and/or chemical vapor deposition (CVD), a dielectric material may be filled in to recess 335. In embodiments, suitable dielectric materials may include silicon oxide, silicon nitride, combinations thereof, as well as other dielectrics as known in the art.

By utilizing optional operation 210, the protective layer 330 may be formed by oxidation of the sidewalls of access aperture 325 at operation 215. Namely, by utilizing optional filling operation 210, the protective layer 330 may be blocked from forming within recess 335, and may therefore form on vertically extending sidewalls 340 of access aperture 325. Moreover, by utilizing optional filling operation 210, sidewall oxidation or nitridation as known in the art may be utilized to form protective layer 330 without requiring extensive processing. Moreover, the dielectric material filed into recess 335 may be easily removed after formation of protective layer 330 by one or more selective etch processes, allowing for further processing without damaging protective layer 330. Nonetheless, in embodiments, it may be desirable to perform one or more cleaning operations, such as a Siconi™ clean, to remove any surface oxides present prior to formation of protective layer 330.

However, as discussed above, in embodiments, no optional filling operation 210 may be necessary. Instead, a directional deposition may be utilized to deposit protective layer 330 on vertically extending sidewalls 340 of access aperture 325. While various deposition methods may be utilized as known in the art, in embodiments, the directional deposition operation may include physical vapor deposition (PVD), ion beam deposition (IBD), electron beam (EB) deposition, electron beam ion-assisted deposition (EB-IAD), or combinations thereof. Nonetheless, the protective layer 330 may be formed from one or more materials, such as one or more of the dielectric materials discussed above. Namely, by utilizing one or more directional deposition operations at operation 215, a protective layer 330 may be formed predominantly on sidewalls 340 of access aperture 325, due to the selection of one or more line of sight deposition methods. Thus, little to no protective layer 330 may be formed within recesses 335.

Nonetheless, as discussed above, in embodiments, protective layer 330 may be formed at operation 215 without removing a portion of the sacrificial material at operation 205 or filing the formed recess at operation 210. For instance, in embodiments where the sacrificial material is not susceptible to nitridation, as an example, the access aperture 325 may be subject to a nitridation operation at operation 215, forming a nitrogen containing protective layer 330. For instance, in this example, the protective layer may include silicon nitride. However, it should be understood that one or more additional dielectric forming processes may be utilized based upon the materials selected for the sacrificial material and semiconductor material, provided that the dielectric forms on the semiconductor material 310, but does not form on the sacrificial material 315.

Notwithstanding the method(s) utilized to form protective layer 330, the method may be carried out for a time sufficient to form a protective layer having a thickness of greater than or about 5 Å, such as greater than or about 6 Å, such as greater than or about 7 Å, such as greater than or about 8 Å, such as greater than or about 9 Å, such as greater than or about 10 Å, such as greater than or about 15 A, such as greater than or about 20 A, such as greater than or about 30 Å, such as greater than or about 40 Å, such as greater than or about 50 Å, such as greater than or about 75 Å, such as greater than or about 100 Å, such as greater than or about 125 Å, such as greater than or about 150 Å, such as greater than or about 175 Å, such as greater than or about 200 Å, such as greater than or about 250 Å, such as greater than or about 300 Å, such as greater than or about 350 Å, such as greater than or about 400 Å, such as greater than or about 450 Å, such as greater than or about 500 Å, or any ranges or values therebetween. In such a manner, the protective layer 330 may have a sufficient thickness to protect the sidewall 340 of access aperture 325 without impeding the subsequent operations.

Thus, regardless of whether a portion of the sacrificial material is removed at operation 205 or whether the formed recess is filled at operation 210, a protective layer 330 may be formed on access aperture 325 sidewalls 340 as illustrated in FIG. 3C (e.g. vertically extending sidewalls). If not completed at operation 205, or if filled at operation 210, operation 220 may include laterally removing the sacrificial material from at least a portion of recess 335 or removing the dielectric material filled at operation 210. In embodiments, the lateral removal may include any one or more of the embodiments discussed above in regards to optional operation 205.

In such a manner, an etch process specific to the semiconductor material 310 may be utilized at trimming operation 225, as illustrated in FIG. 3D. Namely, by utilizing the protective layer 330 discussed herein, a semiconductor material specific etch process may be utilized without reducing the width w of access aperture 325. Furthermore, as discussed above, surprisingly, such processes are also compatible with relatively thin sacrificial material layers 315. For instance, unlike conventional systems where only the sacrificial material was removed to form the channel (e.g. the thickness of the sacrificial material layer determined the maximum thickness of the formed isolation recess 350), the semiconductor material is etched during trimming.

Moreover, surprisingly, the protective layer 330 protects the vertically extending sidewall 340 of access aperture 325 (e.g. lateral edge of the formed channel) without inhibiting etching from the respective recesses 335. Thus, the protective layer 330 advantageously allows etching from within the recess 335 formed by removal of the sacrificial material while preventing removal of material from the lateral edge. In such a manner, the width w of the access aperture 325 is maintained while allowing the channel 345 to be thinned, forming a robust isolation recess 350.

For instance, unlike conventional processes and devices, the width w of the access aperture may generally retain its originally etched width. Thus, in embodiments, the width of the access aperture after trimming operation 225 may have a width that is less than or about 10% larger than the width of the access aperture prior to trimming (e.g. the access aperture formed via masking and etching discussed above), such as less than or about 9%, less than or about 8%, less than or about 7%, less than or about 6%, less than or about 5%, less than or about 4%, less than or about 3%, less than or about 2%, less than or about 1% larger, or any ranges or values therebetween. As would be understood, in embodiments, some width may be lost to one or more cleaning or removal operations, but the width is largely maintained during trimming.

Thus, in embodiments, the methods according to the present technology may provide excellent channel 345 and isolation 350 thicknesses, while also exhibiting improved mechanical stability and increased channel length. For instance, the channel width c may be less than or about 50 nm, such as less than or about 45 nm, such as less than or about 40 nm, such as less than or about 35 nm, such as less than or about 30 nm, such as less than or about 25 nm, such as less than or about 20 nm, or such as greater than or about 10 nm, such as greater than or about 12.5 nm, such as greater than or about 15 nm, such as greater than or about 17.5 nm, such as about 10 nm, or any ranges or values therebetween.

Moreover, an isolation width I may be greater than or about 40 nm, such as greater than or about 45 nm, such as greater than or about 50 nm such as greater than or about 55 nm, such as greater than or about 60 nm, or such as less than or about 100 nm, such as less than or about 95 nm, such as less than or about 90 nm, such as less than or about 85 nm, such as less than or about 80 nm, such as less than or about 75 nm, such as less than or about 70 nm, such as less than or about 65 nm, such as about 60 nm, or any ranges or values therebetween.

Surprisingly, the width w of the access aperture may be less than 150 nm, such as less than or about 140 nm, such as less than or about 135 nm, such as less than or about 130 nm, such as less than or about 125 nm, such as less than or about 120 nm, such as less than or about 115 nm, such as less than or about 110 nm, such as less than or about 105 nm, such as less than or about 100 nm, such as less than or about 95 nm, such as less than or about 90 nm, or such as greater than or about 50 nm, such as greater than or about 55 nm, such as greater than or about 60 nm, such as greater than or about 65 nm, such as greater than or about 70 nm, such as greater than or about 75 nm, such as greater than or about 80 nm such as greater than or about 85 nm, such as greater than or about 90 nm, such as greater than or about 95 nm, or any ranges or values therebetween.

As illustrated in FIG. 3E, at operation 230, the protective layer 330 may be removed after the isolation recess 350 is trimmed to the desired size. The protective layer 330 may be removed by any suitable etching processes, such as a wet or dry etching process. For example, when the protective layer 330 is silicon nitride, a hot phosphoric acid etch process may be used to remove the protective layer 330.

After removal of the protective layer 330, the semiconductor device 300 may generally re-enter a standard process flow. For instance, in embodiments, gate oxide 402, a diffusion barrier 404 (such as TiN in embodiments), one or more gate metals 406, and one or more isolations 408 may be formed in isolation recess 350, as well as one or more insulative dielectric materials 410 formed in access aperture 325, as may be illustrated in FIG. 3F, forming the capacitor of semiconductor device 300 in the formed isolation recess 350.

However, surprisingly, the methods discussed herein may also be applicable for forming the transistor on an opposite side of semiconductor device 300. Thus, in embodiments, one or more second access apertures 425 may be formed on outer sides 405 of semiconductor device 300. Furthermore, a protective layer 430 may be formed along one or more sidewalls 440 of the one or more second access apertures 425. Moreover, in embodiments, a remainder of the sacrificial material 315, if any, may be removed from the recess, according to any one or more of the methods discussed above.

By utilizing protective layer 430, which may be formed according to any one or more of the above methods, the remainder of isolation recess 350 may be selectively etched as discussed above, providing for a recess 470 to form one or more transistor components, as illustrated in FIG. 3G. Surprisingly, as discussed above, by utilizing protective layer 430, the lateral edge of channel 445 may be maintained while trimming the transistor recess 470 (e.g. trimming recess 335 remaining after formation of isolation recess 350). Thus, little to no channel length may be lost due to etching processes on a capacitor side or a transistor side of the semiconductor device 300.

Nonetheless, as illustrate in FIG. 3H, the protective layer 430 may be removed utilizing any one or more of the methods discussed above after the desired channel width and/or isolation recess width is achieved. In embodiments, the thicknesses may be any one or more of the thicknesses discussed above in regards to the channel, recess, and access aperture. After removing protective layer 430, the semiconductor structure 300 may again reenter a standard process flow, forming transistor components and the remainder of the 3D DRAM capacitor components, in this example, such as one or more source/drain regions 480, bit line 482 patterning and fill, electrode 484 formation and the like. However, as discussed herein, while 3D DRAM has been utilized as an example, it should be clear that the present methods are suitable for forming one or more blind recesses in a variety of devices, including high aspect ratio devices.

In embodiments, forming the protective layer 330/430 may include one or more plasma precursors to the semiconductor structure 300. In embodiments, a deposition precursors may include at least one nitrogen-containing precursor, at least one oxygen-containing precursor, at least one silicon-containing precursor, combinations thereof, and other dielectric precursors as known in the art. The silicon-containing precursor may be or include silane and disilane, among other silicon containing precursors useful in semiconductor processing. The nitrogen-containing precursor may be or include ammonia (NH3) and mixtures of molecular nitrogen and hydrogen (N2+H2), among other nitrogen-containing precursors useful in semiconductor processing. The deposition precursors may also include at least one carrier gas. Embodiments of carrier gases may include molecular nitrogen (N2), helium, xenon, or argon, among other carrier gases useful in semiconductor processing. The oxygen-containing precursor may be any oxygen-containing material used or useful in semiconductor processing. For example, the oxygen-containing precursor may be or include steam (H2O), molecular oxygen (O2), ozone (O3), nitrous oxide (N2O), hydrogen peroxide (H2O2), an oxygen-containing plasma, an alcohol-based compound, or an alcohol-based plasma.

Embodiments of method 200 may further include generating plasma effluents of the deposition precursors in the processing region of the semiconductor processing chamber at in order to form the protective layer at operation 215, as well as at optional operation 210. The deposition plasma may be generated by delivering plasma power to the deposition precursors that have flowed into the processing region. In some embodiments, the plasma power may be delivered by a source of radio frequency (RF) power that is electrically coupled to at least one electrode within the semiconductor processing chamber. In embodiments, the RF power source may deliver power to the at least one electrode, which creates an electric field in the processing region of the semiconductor processing chamber that energizes the deposition precursors to form the deposition plasma. The plasma power delivered to the deposition precursors may be less than or about 60 Watts, less than or about 55 Watts, less than or about 50 Watts, less than or about 45 Watts, less than or about 40 Watts, less than or about 35 Watts, less than or about 30 Watts, or less. The frequency of the RF power delivered to the deposition precursors may be 13.56 MHz in one non-limiting example. In some embodiments, the plasma power delivered to the deposition precursors may be supplied continuously, while in additional embodiments, the plasma power may be pulsed. In pulsed embodiments, the delivered RF plasma power may have a pulsing frequency that may be less than or about 10 kHz, and may be less than or about 9 kHz, less than or about 8 kHz, less than or about 7 kHz, less than or about 6 kHz, less than or about 5 kHz, less than or about 4 kHz, less than or about 3 kHz, less than or about 2 kHz, less than or about 1 kHz, or less. In some pulsed embodiments, the off portion of the plasma power's duty cycle may allow more diffusion of the plasma effluents in the as-deposited silicon-and-nitrogen-containing material. The longer diffusion time for the plasma effluents may form a more uniform as-deposited material.

In embodiments, the deposition of the protective layer within the access aperture(s) may be conducted at a deposition temperature that influences the deposition rate of the material. For example, the processing region of the semiconductor processing chamber may be characterized by a deposition temperature less than or about 550° C., less than or about 500° C., less than or about 475° C., less than or about 450° C., less than or about 425° C., less than or about 400° C., less than or about 375° C., less than or about 350° C., or less than or about 300° C., or less. By depositing at temperatures below or about 500° C., the present technology may protect device thermal budgets.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. “About” and/or “approximately” as used herein and in the appended claims when referring to a measurable value such as an amount, a temporal duration, and the like, encompasses variations of ±20%, ±10%, ±5%, or ±0.1% from the specified value, as such variations are appropriate to in the context of the systems, devices, circuits, methods, and other implementations described herein. “Substantially” as used herein and in the appended claims when referring to a measurable value such as an amount, a temporal duration, a physical attribute (such as frequency), and the like, also encompasses variations of ±20%, ±10%, ±5%, or ±0.1% from the specified value, as such variations are appropriate to in the context of the systems, devices, circuits, methods, and other implementations described herein.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a substrate to a processing region of a semiconductor processing chamber, wherein the substrate comprises one or more alternating pairs of a semiconductor material layer and a sacrificial material layer;
forming one or more vertically extending features through the one or more alternating pairs of semiconductor material layer and sacrificial material layer, forming one or more sidewalls comprising alternating exposed lateral ends of the semiconductor material layer and the sacrificial material layer;
forming a protective material layer over the exposed lateral ends of the semiconductor material layer;
laterally recessing at least a portion of the sacrificial material layer from the one or more vertically extending features; and
trimming a portion of the semiconductor material layer adjacent to the one or more vertically extending features.

2. The semiconductor processing method of claim 1, wherein the protective material layer is formed by selective oxidation or nitridation of the exposed lateral ends of the semiconductor material.

3. The semiconductor processing method of claim 1, wherein the sacrificial material is laterally recessed before forming the protective material layer.

4. The semiconductor processing method of claim 3, further comprising filling the laterally recessed portion of the sacrificial material with a dielectric material.

5. The semiconductor processing method of claim 4, further comprising removing the dielectric material prior to trimming.

6. The semiconductor processing method of claim 1, the protective material layer is formed by directional deposition on the exposed lateral ends of the semiconductor material.

7. The semiconductor processing method of claim 1, wherein a thickness of the protective material layer is from about 5 Å to about 500 Å.

8. The semiconductor processing method of claim 1, wherein the semiconductor material layer is an optionally doped silicon material, and the sacrificial material layer comprises silicon germanium.

9. The semiconductor processing method of claim 1, wherein the one or more vertically extending features has a first width prior to the trimming the semiconductor material layer and a second width after the trimming of the semiconductor material layer, wherein the second width is less than or about 10% larger than the first width.

10. The semiconductor processing method of claim 1, wherein the semiconductor material layer has a thickness that is greater than or about 400% more than a thickness of the sacrificial material layer.

11. The semiconductor processing method of claim 1, further comprising removing the protective material layer after trimming the semiconductor material layer.

12. A semiconductor processing method comprising:
providing a substrate to a processing region of a semiconductor processing chamber, wherein the substrate comprises alternating pairs of a silicon-containing material and a silicon-and-germanium-containing material;
etching one or more access apertures through the alternating pairs of the silicon-containing material and the silicon-and-germanium-containing material, exposing lateral ends of the alternating pairs of the silicon-containing material and the silicon-and-germanium-containing material, wherein the etching forms one or more sidewalls comprising the alternating exposed lateral ends of the alternating pairs of the silicon-containing material and the silicon-and-germanium-containing material;
forming a protective material layer over the exposed lateral ends of the silicon-containing material;
laterally recessing at least a portion of the silicon-and-germanium-containing material from the one or more access apertures; and
trimming a portion of silicon-containing material adjacent to the access aperture.

13. The semiconductor processing method of claim 12, wherein the substrate comprises greater than 20 alternating pairs of the silicon-containing material and the silicon-and-germanium-containing material.

14. The semiconductor processing method of claim 12, wherein a thickness of the silicon-and-germanium-containing material is less than or about 30 nm.

15. The semiconductor processing method of claim 12, wherein the silicon-containing material has a thickness that is greater than or about 400% more than a thickness of the silicon-and-germanium-containing material.

16. The semiconductor processing method of claim 12, further comprising, etching one or more vertically extending features at an end of the alternating pairs of the silicon-containing material and the silicon-and-germanium-containing material opposed to the exposed lateral ends, exposing outer ends of the alternating pairs of the silicon-containing material and the silicon-and-germanium-containing material, wherein the etching removes at least a portion of the alternating pairs and forms one or more outer sidewalls comprising the alternating exposed outer ends of the alternating pairs of the silicon-containing material and the silicon-and-germanium-containing material; and
forming a second protective layer over the exposed outer ends of the silicon-containing material.

17. The semiconductor processing method of claim 16, further comprising laterally recessing at least a portion of the silicon-and-germanium-containing material from the one or more vertically extending features.

18. The semiconductor processing method of claim 17, further comprising trimming a portion of the silicon containing material adjacent to the access aperture.

19. A method of forming a three-dimensional dynamic random-access memory (3D DRAM) device, comprising:
providing a substrate to a processing region of a semiconductor processing chamber, wherein the substrate comprises one or more alternating pairs of a silicon-containing material layer and a silicon-and-germanium-containing material layer;
forming one or more access apertures through the one or more alternating pairs of the silicon-containing material layer and the silicon-and-germanium-containing material layer, forming one or more sidewalls comprising alternating exposed lateral ends of the silicon-containing material layer and the silicon-and-germanium-containing material layer;
forming a protective material layer over the exposed lateral ends of the silicon-containing material layer;
laterally recessing at least a portion of the silicon-and-germanium-containing material layer from the one or more access apertures; and
trimming a portion of the silicon-containing material layer adjacent to the one or more access apertures.

20. The method of claim 19, further comprising, etching one or more vertically extending features at an end of the alternating pairs of the silicon-containing material layer and the silicon-and-germanium-containing material layer opposed to the exposed lateral ends, exposing outer ends of the alternating pairs of the silicon-containing material layer and the silicon-and-germanium-containing material layer, wherein the etching removes at least a portion of the alternating pairs and forms one or more outer sidewalls comprising the alternating exposed outer ends of the alternating pairs of the silicon-containing material layer and the silicon-and-germanium-containing material layer; and
forming a second protective layer over the exposed outer ends of the silicon-containing material.
